(19) United States
(12) Patent Application Publication
(10) Pub. No.: US 2004/0014306 A1
(43) Pub. Date: Jan. 22, 2004

(54) Ms type transistor and its manufacturing method

(76) Inventor: Hiroshi Komatsu, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/363,823

(22) PCT Filed: Jun. 27, 2002
(86) PCT No.: PCT/JP02/06485

(30) Foreign Application Priority Data
Jul. 10, 2001 (JP) 20001-209301

(51) Int. Cl. H01L 29/76; H01L 21/3205

(52) U.S. Cl. 438/585; 257/412; 438/592; 257/413; 257/407

(57) ABSTRACT

An MIS transistor that permits freely controlling in a continuous manner a work function in relation to a gate insulation film of a gate electrode to values that differ from a characteristic value of the material that constitutes the gate electrode and, as a result, permits continuously controlling a Vₜₕ. For MIS transistors (100A) and (100B), the gate electrode (10) has a multi layer structure of metal layers (11), (12), (13) of metals having distinct work functions and, moreover, the first metal layer (11) that is in contact with the gate insulation film (2) is formed at film thickness of 5 debye length of less, by atomic layer CVD.

### TECHNICAL FIELD

The present invention relates to a technology for MIS transistors having a semiconductor/insulation film/metal lamination structure, for controlling a threshold value Vₜₕ of a transistor upon permitting continuous control over a work function of a gate electrode as seen from a gate insulation film.

### BACKGROUND ART

MIS transistors formed over a bulk Si substrate have in general a structure like an N-MOS transistor as shown in FIG. 4A or a P-MOS transistor as shown in FIG. 4B, in which a gate insulation film 2 is formed over a N well 1_{N} or a P well 1_{P} of the Si substrate and a n+Poly Si gate electrode 3_{N} or a n+Poly Si gate electrode 3_{P} is further laminated over the gate insulation film 2. Its has to be noted that in the drawings, symbol 4 represents a gate electrode's sidewall, symbol 5 represents a LOCOS isolation, symbol 6 represents an expanded source or expanded drain area and symbol 7 represents an interlayer insulation film.

Conventionally, such transistor threshold Vₜₕ has been controlled by impurity concentration of channel 8. For LSI's under design rules of the magnitude of 0.18 μm, the control of the impurity concentration of channel 8 has been carried out relatively satisfactorily upon application of ion injection technology and short time heating process technology.

However, for transistors under a design rule of 0.1 μm or later, under the methodology of controlling the Vₜₕ with the quantity of channel impurities, the absolute number of impurities contributing to the Vₜₕ for each single transistor is reduced as the channel length goes shorter, thus the variation of Vₜₕ due to statistical fluctuation cannot be no more ignored (Mizuno, T. et al, “Performance Fluctuations of 0.10 μm MOSFETs—Limitation of 0.1 μm ULSIs” etc., Symp. On VLSI Technology '94). In view of this situation, there is longing for realizing control over the transistor Vₜₕ through a work function of the gate electrode as a process for minute devices, other than the control of the impurity concentration of the channel.

On the other hand, in transistors utilizing SOI (Silicon On Insulator) substrates, as the active SOI layer being as thin as several tens of nm, the control of the Vₜₕ through control of impurity concentration has theoretical limitations even for design rules of a magnitude of 0.25 μm. In addition, increasing the impurity concentration of the channel to a high level of 1×10¹⁸ cm⁻³ or more, for example, is not desirable as the mobility of the carrier falls due to an increase in impurity dispersion, thus reducing the electric current driving capability and, furthermore, as an increase in dependency of the Vₜₕ on the thickness of the SOI film cannot be ignored any further. In view of this situation, even for transistors utilizing SOI substrates, it is desired to make it possible to control the transistor Vₜₕ through the work function of the gate electrode.

In addition, it is necessary that the gate electrode is formed from metal in order to provide reduced resistance of the gate electrode as well as to avoid depletion of the gate electrode, thus, also for that purpose, it is desirable to control the Vₜₕ through controlling the work function of the gate electrode.

However, the transistor threshold value Vₜₕ is necessarily determined by the structure of the transistor device (the channel impurity concentration, the thickness of the gate insulation film and the like) upon determining the material of the gate electrode, thus, there has been an inconvenience in which, if the gate electrode is formed simply from metal, it was possible to fabricate transistors having only one type of Vₜₕ.

As a countermeasure, experimental trial has been carried out towards controlling various values of the work function with a same material by utilizing polycrystal TiN as a gate electrode material and changing orientation of the polycrystal TiN (Nakajima, K. et al, 1999 Symposium on VLSI Technology Digest of Technical Papers, p.95 (1999)). However, with this methodology, the controllable range of the work function is basically limited to the range of the difference in work function caused by a crystal orientation (usually, up to the magnitude of 0.1V), thereby there is a fundamental problem in which it is not possible to continuously control the work function and, furthermore, as it is almost impossible to establish 100% control over the orientation of the polycrystal, there are many drawbacks for application of this methodology to minute transistors, from the viewpoints of reproducibility, yield and the like.

In addition, the inventor of the present invention has proposed a methodology in which an insular region made of Silicon and the like by CVD process is first formed as a gate electrode over a gate oxide film, then a thin film of material that differs from the material constituting the insular region is laminated on the insular region, and, upon changing the coverage related to the insular region and gate oxide film, the work function of the gate electrode is changed (Japanese Laid Open H7-211896). However, there is a drawback in this methodology in which, as a result of miniaturization of the device, there is increased dispersion in the characteristics of the device as it is not possible to keep the coverage of the insular region uniform within a single device.

In consideration to such prior art as described above, the present invention aims at freely and continuously controlling the value of the work function of a MIS transistor as seen from the gate insulation film of the gate electrode, to a value that differs from the characteristic value that the material of the gate electrode has, thereby permitting continuous control of the Vₜₕ.

### DISCLOSURE OF THE INVENTION

The inventor of the present invention has conceived that, when forming a gate electrode of a MIS transistor by utilizing a laminated film made of metals having a plurality of different types of work functions, upon forming a first metal layer that is in contact with the gate insulation film having a film thickness of 5 debye length (in other words, a film a few atoms high) or less and laminating a second metal layer thereon, is possible to continuously control the effective work function between the specific work function of the first metal layer and the specific work function of the second metal layer, as seen from the gate insulation film side and, in this case, if the first metal layer is formed by atomic layer CVD (Atomic Layer Chemical Vapour Deposition: ALCVD), it is possible to form it under a designated film thickness as thin as 5 debye length or less with satisfactory reproducibility and in a stable manner.

In other words, the present invention proposes a MIS transistor characterized in that the gate electrode has a multi layer structure of metal layers having different types of work function, and the first metal layer that is in contact with the gate insulation layer is formed by atomic layer CVD and has film thickness of 5 debye length or less.

In addition, the present invention proposes a MIS transistor manufacturing method for forming a gate electrode by laminating gate electrode material on a gate insulation film, the MIS transistor manufacturing method characterized in that in first place, a first metal layer is formed as the gate electrode material on the gate insulation film by atomic layer CVD and having a film thickness of 5 debye length or less, and a second metal layer of a metal that differs from the first metal layer is formed thereon.

### BRIEF DESCRIPTION OF THE DRAWINGS

FIG. 1A to FIG. 1B show schematic cross sectional views of a MIS transistor according to the present invention.

FIG. 2A to FIG. 2E show diagrams for describing a method of manufacturing method of a MIS transistor according to the present invention.

FIG. 3 shows a schematic cross sectional view of another aspect of a MIS transistor according to the present invention.

FIG. 4A to FIG. 4B show schematic cross sectional views of a conventional MOS transistor.

### BEST MODES FOR CARRYING OUT THE INVENTION

The present invention is described in detail below, with reference to the drawings. It is to be noted that, within each drawing, a same symbol represents a same or similar constitutive element.

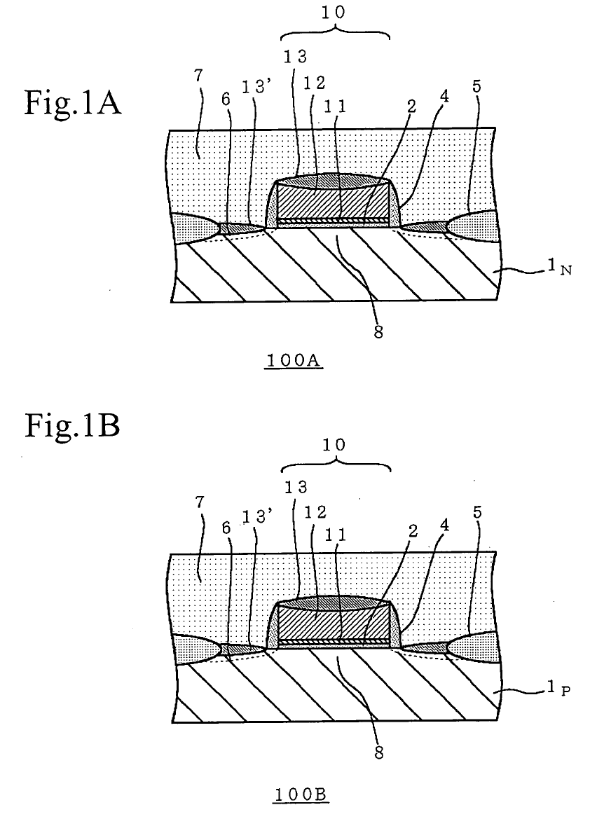

FIG. 1 to FIG. 1B show respectively schematic cross-sectional views of a N-MOS transistor 100A or a P-MOS transistor 100B representing a preferred embodiment of a MIS transistor according to the present invention. These transistors 100A and 100B have a multi layer structure in which a gate electrode 10 formed on a gate insulation film 2 made of SiO₂ over a N well 1_{N} or a P well 1ₚ of a bulk Si substrate has a first metal layer 11 made of Tungsten (W), a second metal layer made of n+PolySi or p+PolySi and a third metal layer made of CoSi₂. It has to be noted that, in the drawings, the symbol 13′ includes a metal layer made of a metal of same type as the third metal layer 13 formed on an extended source or an extended drain area 6.

Here, the first metal layer 11 is formed so as to have a film thickness of 0.6 debye length to 5 debye length (in other words, from 0.1 atomic layer to several atomic layer). The second metal layer 12 is formed so as to have a film thickness of 50 to 300 nm and made thoroughly as a semiconductor (n+PolySi or p+PolySi) by doping PolySi with Phosphorus (P) of concentration of approximately 5×10²⁰cm⁻³ (N-MOS transistor: 100A) or Boron (B) (P-MOS transistor: 100B). In addition, the third metal layer 13 is formed so as to have 10 to 100 nm.

In the present invention, as in such transistors 100A and 100B, by forming the first metal layer 11 thin having a film thickness of 5 debye length or less, an effective work function as seen from the gate insulation film 2 of the gate electrode 10 is a work function determined by the type of metal of the first metal layer 11, an intermediate work function of a work function determined by the type of metal of the second metal layer 12 and, furthermore, it is possible to obtain a desired value upon continuously varying such value by the film thickness of the first metal layer 11. The reason why it is possible to control the work function by controlling the film thickness of the first metal layer 11 in the way described here relies on the fact that, as the influence of the second metal layer 12 is shielded by the first metal layer 11, the influence of the second metal layer 12 as seen from the gate insulation film 2 is drastically reduced to 1/e according to an increase by 1 debye length of the film thickness of the first metal layer 11 and, if the film thickness of the first metal layer 11 exceeds 5 debye length, the influence of the second metal layer 12 is in effect cancelled (reference to Appl. Phys. Lett., 54(3), p. 268 (1989)).

It is to be noted that, when thinly forming the first metal layer 11, it is possible to form the first metal layer 11 to have less than 1 atomic layer, i.e., to have, not a continuous layer of metal atoms, but to have the metal atoms formed discretely over the gate insulation film so as not to overlap with one another.

In the present invention, in order to form the first metal layer 11 on the gate insulation layer 2 upon controlling the film thickness at an atomic layer level, constitutive atoms for the first metal layer 11 are deposited by atomic layer CVD process having film thickness of 1 layer or less each. The atomic layer CVD, being different from conventional MBE (Molecular Beam Epitaxy), does not necessarily require a crystal plate as a substrate and, in addition, as not requiring a considerably high vacuum condition, it is possible to grow a thin film at atomic layer level with satisfactory controllability on a non-crystalline gate insulation layer of SiO₂ and the like.

In addition, in the atomic layer CVD, as a non-adsorption site is masked at time of gas molecule adsorption when the gas molecule (precursor) is relatively large as compared to the adsorption site, an atomic layer is not deposited by an operation of 1 cycle of gas molecule adsorption, so that, 1 atomic layer is deposited upon accumulating several cycles in which, in general, approximately 0.1 atomic layer (0.6 debye length) is deposited. As a result, by controlling the number of cycles, it is possible to control the film thickness of the metal layer in a digital manner (reference to “Surface chemistry of materials deposition at atomic layer level, Tuomo Suntola, Applied Surface Science 100/101. 391-398 (1996)).

In the present invention, there is no specific limitation with respect to the lower limit of the film thickness of the first metal layer 11 from the point of view of control of the work function as seen from the gate insulation film 2. As a result, a de facto lower limit to the film thickness of the first metal layer 11 is the lower limit (usually, 0.1 atomic layer) of the film thickness of the atomic layer deposited over the adsorbent in 1 cycle of gas molecule adsorbing process carried out through atomic layer CVD.

Assuming the first metal layer 11 has approximately 3 atomic layers, as a specific example of control of the work function of the gate electrode 10 as seen from the gate insulation film 2 upon control of the film thickness of the first metal layer 11, the work function as seen from the gate insulation film is the work function of approximately Φ_{M} 4.55 eV that the bulk tungsten (W) has, for both the N-MOS transistor 100A and the P-MOS transistor 100B and, although even by making the first metal layer 11 about 1 atomic layer the work function Φ_{M} as seen from the gate insulation film 2 still becomes near 4.55 eV, when the first metal layer 11 is made approximately 0.1 atomic layer, it becomes possible to change the work function Φ_{M} as seen from the gate insulation film 2 linearly and approximately proportionally to the coating ratio of the W atoms that coat the surface of the gate insulation film 2 so that, for the N-MOS transistor 100A, it is possible to control the W film work function Φ_{M} in the range of 4.1˜4.55 eV and, for the P-MOS transistor 100B, it is possible to control in the range of 4.55˜5.2 eV. As a result, upon making the film thickness of the first metal layer 11 at approximately 0.5 atomic layer, it is possible to make the work function Φ_{M} to approximately 4.3 eV for the N-MOS transistor 100A and approximately 4.9 eV for the NMOS transistor 100A.

In the present invention, although it is possible to form the second metal layer 12 relatively thick in order to avoid influence of the third metal layer 13 to the work function as seen from the gate insulation film 2 in a similar way to the above-mentioned transistors 100A and 100B, it is possible to make the work function as seen from the gate insulation film 2 so as to avoid receiving influence, not only from the first metal layer 11 and the second metal layer 12, but also form the third metal layer 13, whenever such need arises. In this case, the second metal layer 12 is also formed by atomic layer CVD to have several atomic layers or less.

The third metal layer 13 may be provided, as a requirement arises, in order to reduce the resistance of the gate electrode 10 or as a mask or an etching stopper and the like at the time of forming a contact in order to avoid introduction of an impurity underneath the gate, such impurity that is introduced at the time of ion injection.

Other than forming the first metal layer 11 by atomic layer CVD as described above, an alternative method of manufacturing a MIS transistor according to the present invention is to adopt a conventional method, for example, by manufacturing the N-MOS transistor 100A of FIG. 1A as shown in FIG. 2A to FIG. 2E.

(1)First, an isolation 5 and a N well 1_{N} is formed on a bulk Si substrate 14 through a conventional LOCOS method (FIG. 2A);

(2)Then, SiO₂ is grown to 1.5 to 4.0 nm, for example, as the gate insulation film 2 (FIG. 2B);

(3)On the gate insulation film 2, a W film of film thickness of 0.6 debye length to 5 debye length (in other words, 0.1 atomic layer to several atomic layers) is deposited as the first metal layer 11, through atomic layer CVD (FIG. 2C). In such case, the conditions for the atomic layer CVD are, for example, substrate temperature of 300° C., WOCL₄ as the precursor and repetition of cycles of a gas flow sequence of influx of WOCL₄, exhaustion of N₂, influx of H₂ and exhaustion of N₂;

(4)On the first metal layer 11 (W film), Poly Si is deposited under conventional CVD process and having film thickness of 50˜300 nm and, in addition, P ions are introduced to the N-MOS transistor-forming region so as to have concentration of 5×10¹⁵ cm⁻² at 20 keV, for example, thus forming the n+PolySi constituting the second metal layer 12 (FIG. 2D). It is to be noted that, when forming the P-MOS transistor, B ions are introduced to the forming region thereof so as to have concentration of 5×10¹⁵ cm⁻² at accelerating voltage of 10 keV, for example, thus forming the p+PolySi. In order to separate the N-MOS transistor forming area and the P-MOS transistor forming area, a resist mask 15 is utilized.

(5)Thereafter, a semiconductor device is completed by sequentially performing forming of a pattern for the gate electrode 10 is formed through a conventional method, injection of impurity to an extended source or an extended drain area 6, forming of a sidewall 4 of the gate electrode 10, injection of impurities to the source S and the drain D and activation thereof, forming of self-aligned metal layers 13 and 13′ made of CoSi₂ on the second metal layer 12 and the extended source or drain area 6, deposition of an interlayer insulation film 7 (FIG. 2E), forming of contact holes, metal filling and forming of wiring.

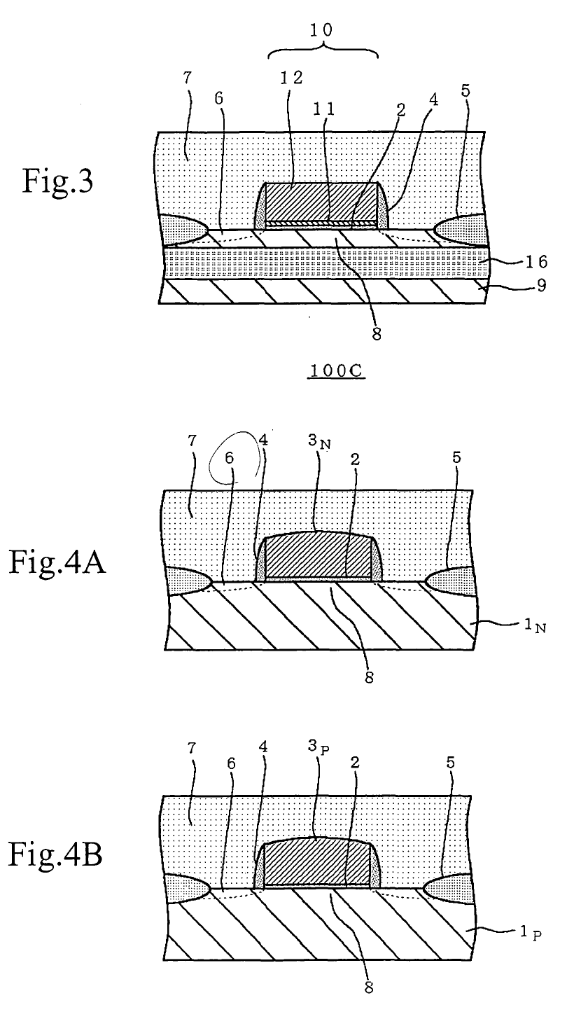

FIG. 3 shows a schematic cross-sectional view of a MIS transistor 100C according to another preferred embodiment of the present invention. In such transistor 100C, the first metal layer 11 is formed of titanium (Ti), the second metal layer 12 is formed of platinum (Pt) and the third metal layer is omitted.

In addition, in this transistor 100C, a SOI substrate 9 (in the figure, symbol 16 indicates an buried oxide film) is utilized as a substrate for forming the transistor and the Vₜₕ is controlled only through the work function of the gate electrode 10, without doping the channel section 8 with impurity as in complete depletion type transistors. By controlling the Vₜₕ in this manner, although it is not possible to separately set the work function of the gate electrodes thereof by adjustment of the impurity concentration, as it is possible to control the film thickness of the first metal layer 11 separately for the N-MOS transistors and the P-MOS transistors, it is possible to realize the desired Vₜₕ for both the N-MOS transistors and the P-MOS transistors.

The MIS transistors according to the present invention may still have various configurations. The type of metal constituting the first metal layer 11, the second metal layer 12 and the third metal layer 13 may be changed ad libitum so that it is possible, for example, to form the first metal layer 11 by replacing the above mentioned W or Ti with other refractory metals such as molybdenum (Mo), tantalum (Ta), zirconium (Zr) and the like. In this case, in order to form the first metal layer 11, the gas molecules (precursor) utilized for the atomic layer CVD may include oxihalides, halides and organic compounds of corresponding metals. Although the film thickness of the metal layer formed by deposition in one cycle of atomic layer CVD changes according to the size of the gas molecule, it is possible to control the first metal layer 11 at a desired thickness by changing the number of cycles.

Although it is possible to determine the second metal layer 12 according to the type of metal constituting the first metal layer 11, it is possible to form the layer with, for example, Pt, lead (Pb), cobalt (Co), iridium (Id) and the like.

In addition, as far as the MIS transistor according to the present invention is concerned, it is possible to apply the transistor to a variety of conventional MIS transistors, as there is no specific limitation for structures except the gate electrode, structures for the source, drain and the like, other than the requirement for the gate electrode 10 to have a multi layer structure as mentioned above. Also, the type of gate insulation film 2 is not limited to a Si oxide film, so that it is possible to utilize high conductive films of oxy-nitro-Si, Ta₂O₅, Al₂O₃ and the like, and the thickness thereof may be changed ad libitum.

According to the MIS transistor of the present invention, as the gate electrode has a multi layer structure of layers of multiple types of metal having different work functions and a layer among such metal layers which is in contact with the gate insulation film is formed by atomic layer CVD to have a thickness of 5 debye length or less, it is possible to freely control the work function of the gate electrode as seen from the gate insulation film in a continuous manner and to values that differ from values that are specific to the material that constitutes the gate electrode. As a result, it becomes possible to reduce the variations in the transistor threshold value Vₜₕ due to statistical fluctuations in the number of impurities corresponding to a single transistor, in comparison to the case in which the Vₜₕ is controlled only by the impurities of the channel, thus permitting setting both the Vₜₕ and the voltage of the power supply to a lower level. As a result, it is possible to make attempts at realizing further low power and higher speed semiconductor devices.

1. A MIS transistor characterized by comprising a gate electrode having a multi layer structure of layers of a plurality of types of metal having different work functions and a first metal layer in contact with a gate insulation film formed by atomic layer chemical vapour deposition (ALCVD) and having a film thickness of 5 debye length or less.

2. The MIS transistor according to claim 1 wherein the film thickness of the first metal layer is 0.6 debye length or more.

3. A MIS transistor manufacturing method for forming a gate electrode by laminating gate electrode material, the MIS transistor manufacturing method characterized by:
forming, as the electrode material, a first metal layer having a film thickness of 5 debye length or less by atomic layer CVD on a gate insulation layer; and
laminating on the first metal layer a second metal layer made of a metal of different type from the first metal layer.

4. The MIS transistor manufacturing method according to claim 3 wherein the film thickness of the first metal layer is 0.6 debye length or more.
